(19) United States
(12) Patent Application Publication
(10) Pub. No.: US 2024/0011168 A1
(43) Pub. Date: Jan. 11, 2024

(54) PHOTOELECTROCHEMICAL DEVICE

(71) Applicant: NATIONAL CHUNG HSING UNIVERSITY, Taichung City (TW)

(72) Inventors: Fu-Hsing LU, Taichung City (TW); Xin-Xian YANG, Taichung City (TW)

(21) Appl. No.: 17/858,548

(22) Filed: Jul. 6, 2022

(51) Int. Cl. C25B 9/50; C23C 14/34; C23C 14/06; C23C 14/08

(52) U.S. Cl. CPC C25B 9/50; C23C 14/3414; C23C 14/0641; C23C 14/083

(57) ABSTRACT

A photoelectrochemical device includes a substrate, a first titanium nitride (TiN) layer coated on the substrate, and a first nitrogen-doped titanium dioxide (N—TiO₂) layer coated on the first TiN layer. The photoelectrochemical device has enhanced photoelectric conversion efficiency and can be made by a simple, effective method, thereby shortening the manufacturing time and lowering the manufacturing cost thereof.

### BACKGROUND OF THE INVENTION

### 1. Field of the Invention

The present invention relates generally to a photoelectric component of semiconductor and more particularly, to a photoelectrochemical device.

### 2. Description of the Related Art

With the rise of environmental awareness in recent years, sustainable and renewable energy issues, such as converting solar energy into chemical fuels that can be conveniently stored and transported, have gradually become mainstream. Compared with solid-state junction devices of photovoltaics, photoelectrochemical devices have the advantages of relatively simpler manufacturing process, economy and wide application fields. The mechanism of a photoelectrochemical device is to use light irradiated on a photoelectrode prepared by semiconductor material to excite the carriers inside the semiconductor medium to make the transition from the valence band (VB) to the conduction band (CB), resulting in carrier flow to produce power, or to produce chemical fuel through the oxidation or reduction of water molecules via carriers.

However, the conventional photoelectrochemical device manufacturing process is complicated and time-consuming, resulting in high cost. Further, the photoelectric conversion efficiency of the conventional photoelectrochemical device also needs to be improved; otherwise, the photoelectrochemical device cannot meet the economic benefits of mass production.

### SUMMARY OF THE INVENTION

The present invention has been accomplished in view of the above-noted circumstances. It is an objective of the present invention to provide a photoelectrochemical device, which has enhanced photoelectric conversion efficiency.

It is another objective of the present invention to provide a photoelectrochemical device, which can be made by a simple manufacturing method so as to shorten the manufacturing time and lower the manufacturing cost.

To attain the above objectives, the present invention provides a photoelectrochemical device comprising a substrate, a first titanium nitride (TiN) layer coated on the substrate, and a first nitrogen-doped titanium dioxide (N—TiO₂) layer coated on the first TiN layer. As a result, the photoelectrochemical device can effectively enhance the photoelectric conversion efficiency and can be effectively made by a simple manufacturing method, thereby shortening the manufacturing time and lowering the manufacturing cost thereof.

### BRIEF DESCRIPTION OF THE DRAWINGS

The present invention will become more fully understood from the detailed description given herein below and the accompanying drawing which is given by way of illustration only, and thus is not limitative of the present invention, and wherein:

FIG. 1 is a schematically sectional view of a photoelectrochemical device according to a first embodiment of the present invention;

FIG. 2 is a schematically sectional view of a photoelectrochemical device according to a second embodiment of the present invention;

FIG. 3 is a diagram illustrating the test results of photocurrent densities of the photoelectrochemical devices of the first and second embodiments;

FIG. 4 is a schematically sectional view of a photoelectrochemical device according to a third embodiment of the present invention;

FIG. 5 is a schematically sectional view of a photoelectrochemical device according to a fourth embodiment of the present invention;

FIG. 6 is a diagram illustrating the test results of photocurrent densities of the photoelectrochemical devices of the third and fourth embodiments; and

FIG. 7 is a schematically sectional view of a photoelectrochemical device according to a fifth embodiment of the present invention.

### DETAILED DESCRIPTION OF THE INVENTION

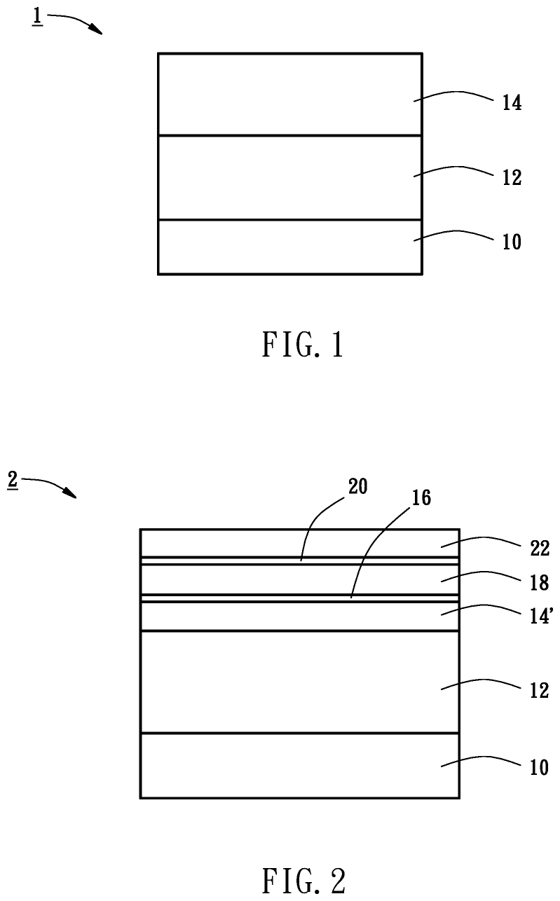

The structure and technical features of the present invention will be detailedly described hereunder by five embodiments and accompany drawings. As shown in FIG. 1, a photoelectrochemical device 1 provided in accordance with a first embodiment of the present invention is composed of a substrate 10, a first titanium nitride (TiN) layer 12, and a first nitrogen-doped titanium dioxide (N—TiO₂) layer 14.

The substrate 10 is made of soda-lime glass, which does not generate photocurrent when it is irradiated by light. However, other materials, such as silicon wafers, transparent conductive glass, and the like, can also be used as the substrate as long as they can facilitate coating of a thin film thereon.

The first TiN layer 12 is deposited and coated on the top surface of the substrate by DC unbalanced magnetron sputtering. During the sputtering process, a titanium metal of 99.99% purity was used as the sputtering target, the background pressure was set at 1.3×10⁻² Pa, the working pressure was maintained at 2.6×10⁻¹ Pa, the DC sputtering power was 350 W, and the worktable supporting the substrate was biased with a current of −50 V. At a temperature of 400° C., a gas mixture of argon (Ar) of 99.999% purity serving as working gas and the dedusted dry air serving as reaction gas was introduced into a vacuum chamber (not shown) under a condition that the flow ratio of air to argon (air/Ar) is about 0.12. In this way, the first TiN layer 12 having a thickness of about 100 nm can be formed and thus serving as a conductive layer for transmitting photocurrent. In accordance with experimental results of the present invention, the flow ratio of air to argon (air/Ar) ranging from 0.08 to 0.2 can also form satisfied first TiN layer 12, and preferably the flow ratio of air to argon (air/Ar) may be set at a range from 0.1 to 0.15 to get a better effect.

The first nitrogen-doped titanium dioxide (N—TiO₂) layer 14 was subsequently deposited and coated on the top surface of the first titanium nitride (TiN) layer 12 in the same sputtering system. In the sputtering process of depositing the first N—TiO₂ layer 14, all operational parameters were similar or identical to the operational parameters in the sputtering process of depositing the first TiN layer 12, except that the flow ratio of air to argon is adjusted to about 1.6. In this way, the first N—TiO₂ layer 14 having a thickness of about 100 nm can be formed and thus serving as a light absorbing layer that can produce carriers when absorbing light. In this embodiment, the first N—TiO₂ layer 14 is a homogeneous layer having a nitrogen content of about 3.9 at % and a photonic bandgap of about 2.9 eV. In accordance with experimental results of the present invention, the flow ratio of air to argon (air/Ar) ranging from 0.4 to 3.0 can also form satisfied first N—TiO₂ layer 14, and preferably the flow ratio of air to Ar (air/Ar) may be set at a range from 1.2 to 2.0 to get a better effect.

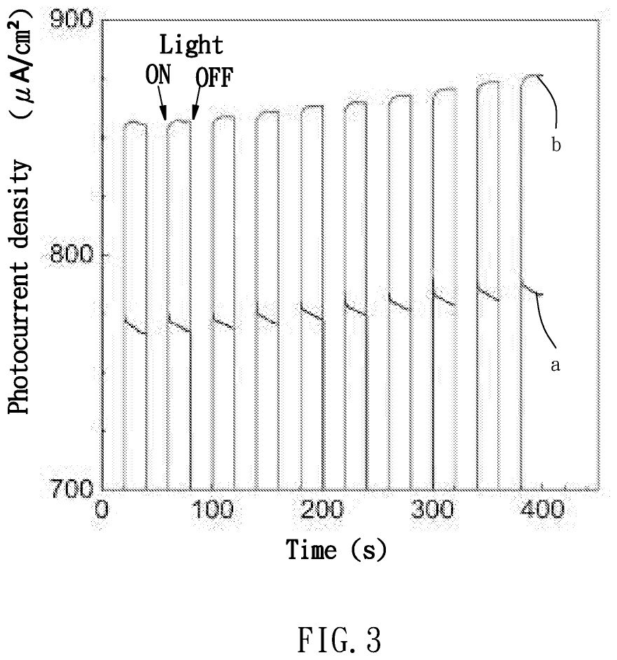

To test the effect of the photoelectrochemical device 1, the photoelectrochemical device 1 was taken as a working electrode, a platinum sheet was used as a counter electrode, and Ag/AgCl was used as a reference electrode. In the KOH electrolyte with a concentration of 1 M, the photoelectrochemical device 1 was irradiated with a xenon arc light source of 100 watt, and then an electrochemical analyzer (CHI 6088D) with a bias voltage of −0.2 V was used to measure the photocurrent density. The actual measurement result was 776±6 μA/cm², as shown as the curve a of FIG. 3. Compared with the conventional photoelectrochemical device, the photoelectrochemical device 1 has an enhanced photoelectric conversion efficiency, and the manufacturing processes can be accomplished in the same sputtering system. In the processes of depositing the first titanium nitride layer 12 and the first nitrogen-doped titanium dioxide layer 14, the manufacturer only needs to adjust/control the flow ratio of air to argon without the need of using purified oxygen and nitrogen, preforming the two sputtering processes in different systems at different times, or performing the sputtering processes under a high-level vacuum condition, thereby effectively saving the vacuuming time. In other words, the photoelectrochemical device 1 can be effectively made by a simple manufacturing method, thereby shortening the manufacturing time and lowering the manufacturing cost so as to achieve the objective of the present invention.

Referring to FIG. 2, a photoelectrochemical device 2 provided in accordance with a second embodiment of the present invention is composed of a substrate 10, a first TiN layer 12, a first N—TiO₂ layer 14′, a second TiN layer 16, a second N—TiO₂ layer 18, a third TiN layer 20, and a third N—TiO₂ layer 22.

In this second embodiment, the substrate 10 and the first TiN layer 12 are structurally same as that of the first embodiment, and thus detailed illustration thereof will not be repeatedly given here. However, the depositing time of the first N—TiO₂ layer 14′ is shorter than that of the first N—TiO₂ layer 14 of the first embodiment, such that the thickness of the first N—TiO₂ layer 14 is about 33 nm only. The second TiN layer 16 is coated on the top surface of the first N—TiO₂ layer 14′, and the manufacturing process thereof is same as that of the first TiN layer 12 but having shorter depositing time, resulting in a thickness of about 4 nm. In this way, the second TiN layer 16 can serve as a light admissible conductive layer, which enables the first N—TiO₂ layer 14′ under the second TiN layer 16 to receive light. The second N—TiO₂ layer 18 is coated on the top surface of the second TiN layer 16, and made by a process same as that of the first N—TiO₂ layer 14′ but having a shorter depositing time, resulting in a thickness of about 33 nm. Such multi-layered structure may be piled one above another. As shown in FIG. 2, on the second N—TiO₂ layer 18, the third TiN layer 20 and the third N—TiO₂ layer 22 are successively deposited.

In this embodiment, a total thickness of the first to third N—TiO₂ layers 14′, 18, and 22 amounts to 99 nm, which is about equivalent to the thickness of 100 nm of the first N—TiO₂ layer 14 of the first embodiment. The technical features of this embodiment lies in that the second TiN layer 16 and the third TiN layer 20 are interposed between the first to third N—TiO₂ layers 14′, 18 and 20. Because the second and third TiN layers 16 and 20 have relatively thinner thickness, major light can still pass through the second and third TiN layers 16 and 20 without affecting the first and second N—TiO₂ layers 14′ and 18 below the second and third TiN layers 16 and 20 to absorb the light energy to generate carriers. Further, the carriers generated due to light irradiation on the first to third N—TiO₂ layers 14′, 18, and 22 only move in a shorter path to be transmitted out from the first to third TiN layers 12, 16 and 20, thereby outputting a photocurrent density higher than that of the photoelectrochemical device 1 of the first embodiment. As shown as the curve b in FIG. 3, the photocurrent density of the photoelectrochemical device 2 can reach 865±7 μA/cm², which is about 11.5% higher than the first embodiment in photoelectric conversion efficiency.

Based on the above-disclosed technical features, various modifications to the photoelectrochemical device of the present invention may be made. For example, the second N—TiO₂ layer 18, the third TiN layer 20 and the third N—TiO₂ layer 22 may partially or totally omitted. Further, the nitrogen contents of the first to third N—TiO₂ layers 14′, 18 and 22 may be the same or different, and preferably the aforesaid nitrogen contents may range from 2.8 at % to 4.2 at %, and more preferably from 3.6 at % to 4.2 at %. Furthermore, the photonic bandgaps of the first to third N—TiO₂ layers 14′, 18 and 22 may be the same or different, and preferably the aforesaid photonic bandgaps may range from 2.8 eV to 3.0 eV. Moreover, the thicknesses of the second and third TiN layers 16 and 20 may be less than 10 nm as long as they allow pass of the light. For the sputtering processes, they may be performed at a temperature from 300° C. to 500° C.

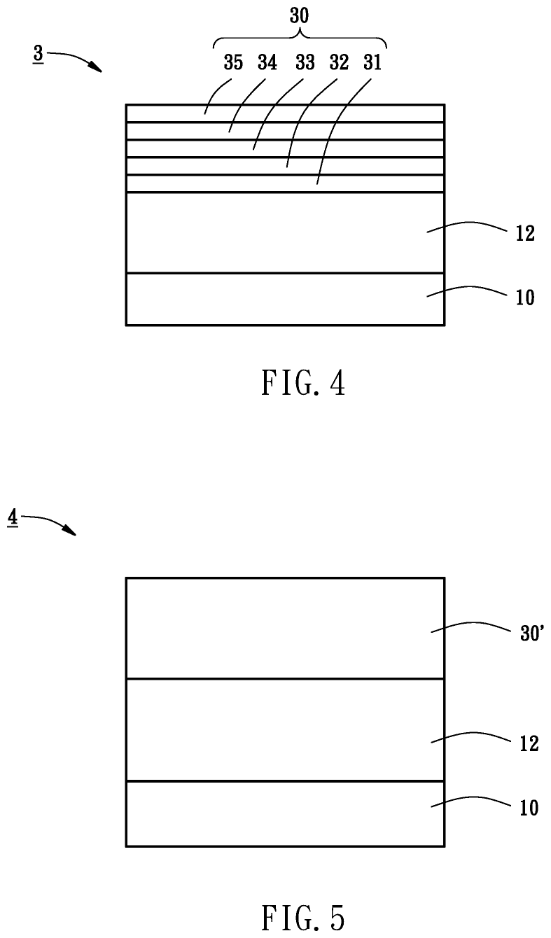

Referring to FIG. 4, a photoelectrochemical device 3 provided in accordance with a third embodiment of the present invention is composed of a substrate 10, a first titanium nitride (TiN) layer 12, and a first nitrogen-doped titanium dioxide (N—TiO₂) layer 30.

In this third embodiment, the structure and manufacturing processes of the substrate 10 and the first TiN layer 12 are same as that of the first embodiment, and thus detailed illustration thereof will not be repeatedly given here. The first nitrogen-doped titanium dioxide (N—TiO₂) layer 30 was subsequently deposited and coated on the top surface of the first titanium nitride (TiN) layer 12 in the same sputtering system. In the sputtering process of depositing the first N—TiO₂ layer 30, all operational parameters were similar or identical to the operational parameters in the sputtering process of depositing the first TiN layer 12, except that the flow ratio of air to argon is adjusted along with the sputtering time in a discrete, stepwise manner from 1.2, 1.4, 1.6, 1.8 to 2.0. In this way, the first N—TiO₂ layer 30 will comprise five sublayers including a first sublayer 31, a second sublayer 32, a third sublayer 33, a fourth sublayer 34, and a fifth sublayer 35, which are successively arranged from the bottom to the top of the first N—TiO₂ layer 30 and each have a thickness of about 20 nm. As such, the first N—TiO₂ layer 30 having a total thickness of 100 nm can be formed and thus serving as a light absorbing layer that can produce carriers when absorbing light. In this embodiment, the nitrogen contents of the first to fifth sublayers 31 to 35 are 3.6 at %, 3.7 at %, 3.9 at %, 4.0 at %, and 4.2 at %, respectively. Further, the photonic bandgaps of the first to fifth sublayers 31 to 35 are 2.9 eV, 2.9 eV, 2.9 eV, 2.8 eV, and 2.8 eV, respectively. In accordance with experimental results of the present invention, the flow ratio of air to argon (air/Ar) ranging from 0.4 to 3.0 can also form satisfied first N—TiO₂ layer 30, and preferably the flow ratio of air to argon (air/Ar) may be set at a range from 0.8 to 2.0 to get a better effect.

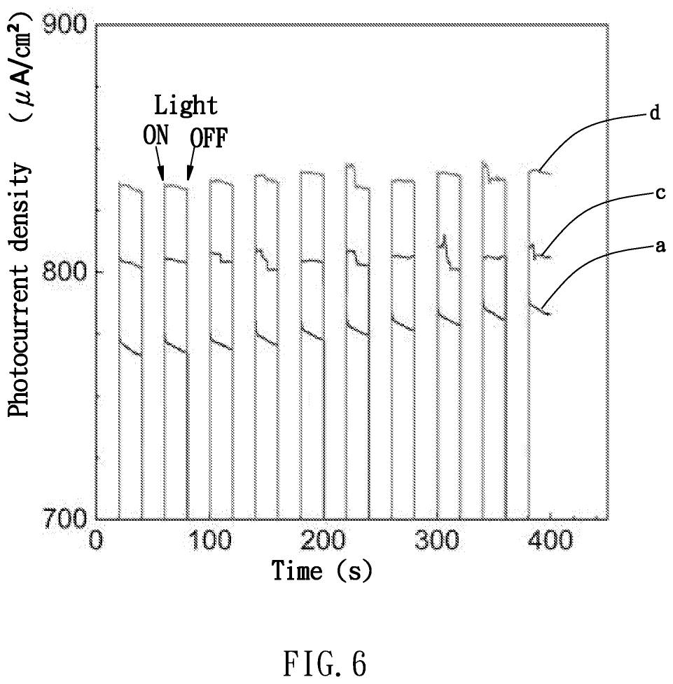

Because the first N—TiO₂ layer 30 possesses various photonic bandgaps facilitating absorption of lights of different wavelengths to produce carriers, the photoelectrochemical device 3 has a great photoelectric conversion efficiency. To test the effect of the photoelectrochemical device 3, the photoelectrochemical device 3 was taken as a working electrode, a platinum sheet was used as a counter electrode, and Ag/AgCl was used as a reference electrode. In the KOH electrolyte with a concentration of 1 M, the photoelectrochemical device 1 was irradiated with a xenon arc light source of 100 watt, and then an electrochemical analyzer (CHI 6088D) with a bias voltage of −0.2 V was used to measure the photocurrent density. The actual measurement result was 805±4 μA/cm², as shown as the curve c of FIG. 6. Compared with the conventional photoelectrochemical device, the photoelectrochemical device 3 has an enhanced photoelectric conversion efficiency, and the manufacturing processes can be accomplished in the same sputtering system. In the processes of depositing the first titanium nitride layer 12 and the first nitrogen-doped titanium dioxide layer 30, the manufacturer only needs to adjust/control the flow ratio of air to argon without the need of using purified oxygen and nitrogen, preforming the two sputtering processes in different systems at different times, or performing the sputtering processes under a high-level vacuum condition, thereby effectively saving the vacuuming time. In other words, the photoelectrochemical device 3 can be effectively made by a simple manufacturing method, thereby shortening the manufacturing time and lowering the manufacturing cost so as to achieve the objective of the present invention. Compared with the measured result of the photocurrent density of the photoelectrochemical device 1 of the first embodiment, as shown as the curve a in FIG. 6, the photoelectrochemical device 3 has a better photoelectric conversion efficiency.

Referring to FIG. 5, a photoelectrochemical device 4 provided in accordance with a fourth embodiment of the present invention is composed of a substrate 10, a first titanium nitride (TiN) layer 12, and a first nitrogen-doped titanium dioxide (N—TiO₂) layer 30′.

In this fourth embodiment, the structure and manufacturing processes of the substrate 10 and the first TiN layer 12 are same as that of the third embodiment, and thus detailed illustration thereof will not be repeatedly given here. The first nitrogen-doped titanium dioxide (N—TiO₂) layer 30′ was subsequently deposited and coated on the top surface of the first titanium nitride (TiN) layer 12 in the same sputtering system. In the sputtering process of depositing the first N—TiO₂ layer 30′, all operational parameters were similar or identical to the operational parameters in the sputtering process of depositing the first TiN layer 12, except that the flow ratio of air to argon is adjusted along with the sputtering time in a continuous manner from 1.2 to 2.0 gradually. In this way, the first N—TiO₂ layer 30′ having a thickness of about 100 nm can be formed. Compared to the first embodiment, because the first N—TiO₂ layer 30′ possesses continuously distributed photonic bandgaps facilitating absorption of comprehensive lights of different wavelengths to produce carriers, the photoelectrochemical device 4 has more enhanced photoelectric conversion efficiency. As shown as the curve b of FIG. 6, the actual measurement result of the photoelectrochemical device 4 reaches 837±3 μA/cm², which is about 40% higher than the third embodiment in photoelectric conversion efficiency.

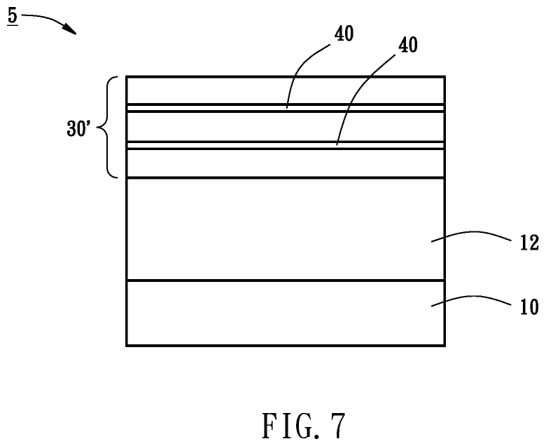

Referring to FIG. 7, a photoelectrochemical device 5 provided in accordance with a fifth embodiment of the present invention is composed of a substrate 10, a first TiN layer 12, a first N—TiO₂ layer 30′, and two thin TiN layers 40. This embodiment is basically same as the fourth embodiment, except that the thin TiN layers 40 are spacedly interposed inside the first N—TiO₂ layer 30′. The manufacturing process of each thin TiN layer 40 is basically same as that of the first TiN layer 12, except that the depositing time of the thin TiN 40 is much shorter to result in a thickness of about 4 nm. In this way, the thin TiN layer 40 can serve as a light admissible conductive layer, which enables the first N—TiO₂ layer 30′ to receive light. Because each of the thin TiN layers 40 has relatively thinner thickness, major light can still pass through the thin TiN layers 40 without affecting the first N—TiO₂ layer 30′ to absorb the light energy to generate carriers. Further, the carriers generated due to light irradiation on the first N—TiO₂ layer 30′ only move in a shorter path to be transmitted out from the thin TiN layers 40, thereby outputting a photocurrent density even higher than that of the photoelectrochemical device 4 of the fourth embodiment.

In accordance with the experimental results of the present invention, as long as the thickness of the thin TiN layer 40 is less than 10 nm, the thin TiN layer 40 will be light admissible. As such, the number of the thin Tin layers 40 is not limited to the one disclosed in this embodiment. That is, one or more thin TiN layers 40 may be adopted according to the actual requirement.

Based on the above-disclosed technical features, various modifications to the photoelectrochemical device of the present invention may be made. For example, the nitrogen contents of the first N—TiO₂ layers 30 and 30′ may vary from the bottom to the top of the first N—TiO₂ layers 30 and 30′ in a discrete, stepwise manner or a continuous manner from 2.5 at % to 4.5 at %, and more preferably from 2.8 at % to 4.2 at %. Furthermore, the photonic bandgaps of the first N—TiO₂ layers 30 and 30′ may vary from the bottom to the top of the first N—TiO₂ layers 30 and 30′ in a discrete, stepwise manner or a continuous manner from 2.6 eV to 3.2 eV, and more preferably from 2.8 eV to 3.0 eV. The aforesaid values may be gradually or randomly increased or decreased from the bottom to the top of the first N—TiO₂ layers 30 and 30′. For the sputtering processes, they may be performed at a temperature from 300° C. to 500° C. The thicknesses of the first titanium nitride 12, the first nitrogen-doped titanium dioxide layers 30 and 30′, and the first to fifth sublayers 31 to 35 may be adjusted in accordance with actual requirement. Such variations are not to be regarded as a departure from the spirit and scope of the invention, and all such modifications as would be obvious to one skilled in the art are intended to be included within the scope of the following claims.

What is claimed is:

1. A photoelectrochemical device, comprising:
a substrate;
a first titanium nitride (TiN) layer coated on the substrate; and
a first nitrogen-doped titanium dioxide (N—TiO₂) layer coated on the first TiN layer.

2. The photoelectrochemical device as claimed in claim 1, wherein the first N—TiO₂ layer is a homogeneous layer having a nitrogen content ranging from 2.8 at % to 4.2 at %.

3. The photoelectrochemical device as claimed in claim 2, wherein the nitrogen content of the first N—TiO₂ layer ranges from 3.6 at % to 4.2 at %.

4. The photoelectrochemical device as claimed in claim 1, wherein the first N—TiO₂ layer has a photonic bandgap ranging from 2.8 eV to 3.0 eV.

5. The photoelectrochemical device as claimed in claim 1, further comprising a second TiN layer coated on the first N—TiO₂ layer.

6. The photoelectrochemical device as claimed in claim 5, wherein the second TiN layer has a thickness less than 10 nm.

7. The photoelectrochemical device as claimed in claim 5, further comprising a second N—TiO₂ layer coated on the second TiN layer.

8. The photoelectrochemical device as claimed in claim 7, wherein the second N—TiO₂ layer is a homogeneous layer having a nitrogen content ranging from 2.8 at % to 4.2 at %.

9. The photoelectrochemical device as claimed in claim 1, wherein the first TiN layer and the first N—TiO₂ layer are both formed by sputtering.

10. The photoelectrochemical device as claimed in claim 9, wherein the first TiN layer is formed by the sputtering using a titanium-containing target and introducing a gas mixture of air and argon into a vacuum chamber at a temperature of 300° C. to 500° C.; in the gas mixture, a ratio of air to argon ranges from 0.08 to 0.2.

11. The photoelectrochemical device as claimed in claim 10, wherein the ratio of air to argon ranges from 0.1 to 0.15.

12. The photoelectrochemical device as claimed in claim 9, wherein the first N—TiO₂ layer is formed by the sputtering using a titanium-containing target and introducing a gas mixture of air and argon into a vacuum chamber at a temperature of 300° C. to 500° C.; in the gas mixture, a ratio of air to argon ranges from 0.4 to 3.0.

13. The photoelectrochemical device as claimed in claim 12, wherein the ratio of air to argon ranges from 1.2 to 2.0.

14. The photoelectrochemical device as claimed in claim 1, wherein the first N-TiO₂ layer has a nitrogen content varying from a bottom of the first N—TiO₂ layer to a top of the first N—TiO₂ layer from 2.5 at % to 4.5 at %.

15. The photoelectrochemical device as claimed in claim 14, wherein the nitrogen content of the first N—TiO₂ layer varies from 2.8 at % to 4.2 at % from the bottom to the top of the first N—TiO₂ layer.

16. The photoelectrochemical device as claimed in claim 14, wherein the first N—TiO₂ layer has a photonic bandgap varying from 2.6 eV to 3.2 eV from the bottom to the top of the first N—TiO₂ layer.

17. The photoelectrochemical device as claimed in claim 16, wherein the photonic bandgap of the first N—TiO₂ layer varies from 2.8 eV to 3.0 eV from the bottom to the top of the first N—TiO₂ layer.

18. The photoelectrochemical device as claimed in claim 14, wherein the first TiN layer and the first N—TiO₂ layer are both formed by sputtering.

19. The photoelectrochemical device as claimed in claim 18, wherein the first N—TiO₂ layer is formed by the sputtering using a titanium-containing target and introducing a gas mixture of air and argon into a vacuum chamber at a temperature of 300° C. to 500° C.; in the gas mixture, a ratio of air to argon varies from 0.4 to 3.0 along with a sputtering time.

20. The photoelectrochemical device as claimed in claim 19, wherein the ratio of air to argon varies from 0.8 to 2.0 along with the sputtering time.

21. The photoelectrochemical device as claimed in claim 14, wherein one or more thin TiN layers are interposed inside the first N—TiO₂ layer; the one or more thin TiN layers each have a thickness less than 10 nm.
